(19) United States
(12) Patent Application Publication
(10) Pub. No.: US 2016/0091794 A1
(43) Pub. Date: Mar. 31, 2016

(54) DRAWING METHOD

(71) Applicant: SCREEN Holdings Co., Ltd., Kyoto (JP)

(72) Inventors: Fumiharu SHIBATA, Kyoto-shi (JP); Yumiko HIRATO, Kyoto-shi (JP); Yasuyuki KOYAGI, Kyoto-shi (JP); Kazuhiro NAKAI, Kyoto-shi (JP)

(21) Appl. No.: 14/859,461

(22) Filed: Sep. 21, 2015

(30) Foreign Application Priority Data
Sep. 30, 2014 (JP) 2014-200121

(51) Int. Cl. G03F 7/20

(52) U.S. Cl. CPC G03F 7/20

(57) ABSTRACT

A drawing method is to draw a pattern on a substrate. First, cumulative exposure amount distribution data containing a cumulative exposure amount to be applied to each position on the substrate is read. Next, a region R11 and a region R12 on the substrate are specified based on the cumulative exposure amount distribution data. The region R11 is a region where the cumulative exposure amount does not exceed Ma corresponding to a maximum exposure amount capable of being applied to the substrate in one exposure scanning by an exposure apparatus. The region R22 is a region where the cumulative exposure amount exceeds Ma. Then, pattern data containing information about an exposure amount for each position in a region including the region R11 is generated. Further, pattern data containing information about an exposure amount for each position in a region including the region R12 is generated.

### BACKGROUND OF THE INVENTION

1. Field of the Invention

The present invention relates to a technique to expose a substrate by irradiating the substrate with spatially modulated light.

2. Description of the Background Art

An exposure apparatus (drawing apparatus) of a direct drawing type not using a mask has received attention in recent years. This exposure apparatus is to generate a pattern such as a circuit on a photosensitive material applied to a substrate by spatially modulating light emitted from a light source according to pattern data indicating the pattern and scanning the photosensitive material on the substrate with the spatially modulated light. A spatial modulator for the spatial light modulation mentioned herein receives light on a modulation surface emitted from the light source and spatially modulates the received light.

As an example, Japanese Patent Application Laid-Open No. 2006-128194 discloses an exposure apparatus including a spatial modulation element (micromirror array) with multiple pixels arranged two-dimensionally to form an optical image through binary control in terms of brightness and darkness. This exposure apparatus is configured in a manner that allows implementation of maskless gray scale lithography by which a pattern having multiple levels of an exposure amount is generated by superposing optical images for each row or each column using an optical system.

Forming a sophisticated 3D pattern on a substrate has been required in recent years. As an example, to generate a pattern of a smooth spherical shape such as a microlens shape, changing an exposure amount at a large number of levels is an indispensable technique. However, in Japanese Patent Application Laid-Open No. 2006-128194, the number of levels of an exposure amount to be provided to a pattern is limited to the number of levels that can be expressed by the spatial modulator. Japanese Patent Application Laid-Open No. 2006-128194 does not disclose a technique of drawing a pattern having levels of a number exceeding the number that can be expressed by the spatial modulator.

### SUMMARY OF THE INVENTION

The present invention is intended for a drawing method of drawing a pattern on a substrate.

The drawing method of a first aspect of the present invention includes the steps of: (a) drawing a pattern on a substrate through irradiation of a region on the substrate including a first region with light spatially modulated based on first pattern data by an exposure apparatus, the first region being a region where a cumulative exposure amount to be applied does not exceed a first maximum exposure amount capable of being applied to the substrate in one exposure scanning by the exposure apparatus; and (b) drawing a pattern on the substrate through irradiation of a region on the substrate including a second region with light spatially modulated based on second pattern data by the exposure apparatus, the second region being a region where the cumulative exposure amount exceeds the first maximum exposure amount, the second pattern data containing information about an exposure amount for each position.

The drawing method of the first aspect allows generation of a pattern in the second region on the substrate with an exposure amount larger than the first maximum exposure amount in the first region. Thus, a pattern to be generated on the substrate is allowed to have levels of an exposure amount of a number larger than the number of levels that can be expressed through one exposure scanning. As a result, a pattern can be generated with an exposure amount at levels of a number larger than the number of levels that can be expressed through one exposure scanning by the exposure apparatus.

According to the drawing method of a second aspect of the present invention, the drawing method of the first aspect further includes the steps of: (c) reading cumulative exposure amount distribution data containing information about a position on the substrate and the cumulative exposure amount for each position, the step (c) being performed before the step (a); (d) specifying the first region and the second region on the substrate based on the cumulative exposure amount distribution data read in step (c); and (e) generating the first pattern data and the second pattern data for the region including the first region specified in the step (d) and for the region including the second region specified in the step (d) respectively, the first pattern data and the second pattern data each containing an exposure amount for each position.

According to the drawing method of a third aspect of the present invention, in the drawing method of the first or second aspect, the step (b) is a step of switching the maximum exposure amount for the exposure apparatus from the first maximum exposure amount to a second maximum exposure amount larger than the first maximum exposure amount and then exposing the region including the second region.

According to the drawing method of the third aspect, a pattern can be drawn in an area of the second region not overlapping the first region with an exposure amount larger than the first maximum exposure amount.

According to the drawing method of a fourth aspect of the present invention, in the drawing method of any one of the first to third aspects, the maximum exposure amount for the exposure apparatus is determined to be the first maximum exposure amount both in the steps (a) and (b).

According to the drawing method of the fourth aspect, exposure scanning based on the first pattern data and exposure scanning based on the second pattern data are performed with the same maximum exposure amount. This allows omission of a process of calibrating a light amount that is to be performed for each exposure scanning. As a result, a pattern can be generated promptly.

It is therefore an object of the present invention to provide a technique capable of generating a pattern easily on a substrate having levels of an exposure amount of a number larger than the number of levels that can be expressed by a spatial modulator.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a side view schematically showing the structure of an exposure apparatus of a preferred embodiment;

FIG. 2 is a plan view schematically showing the structure of the exposure apparatus of the preferred embodiment;

FIG. 3 schematically shows an exposure head of the preferred embodiment;

FIG. 4 is a diagrammatic plan view for explaining exposure scanning of the preferred embodiment;

FIG. 5 is a block diagram showing the structure of a controller of the preferred embodiment;

FIG. 6 shows a flow of processes performed by the exposure apparatus of the preferred embodiment;

FIG. 7 shows a flow of a pattern data generating process of the preferred embodiment in detail;

FIG. 8 shows an example of an exposure pattern together with a cumulative exposure amount distribution;

FIG. 9 conceptually shows an example of generation of pattern data with a fixed maximum exposure amount;

FIG. 10 conceptually shows an example of generation of pattern data with a variable maximum exposure amount; and

FIG. 11 shows a flow of a drawing process of FIG. 6 in detail.

### DESCRIPTION OF THE PREFERRED EMBODIMENTS

A preferred embodiment of the present invention is described below by referring to the drawings. The preferred embodiment described below is an example showing how the present invention is embodied and is not intended to limit the technical range of the present invention. The drawings referred to in the following description are given a common XYZ orthogonal coordinate system and a common θ axis, where appropriate, to clearly show the positions of members relative to each other and a direction where each member operates. To facilitate understanding, in some drawings, the dimension of each part and the number of parts are exaggerated or simplified.

### 1. Overall Structure of Exposure Apparatus 1

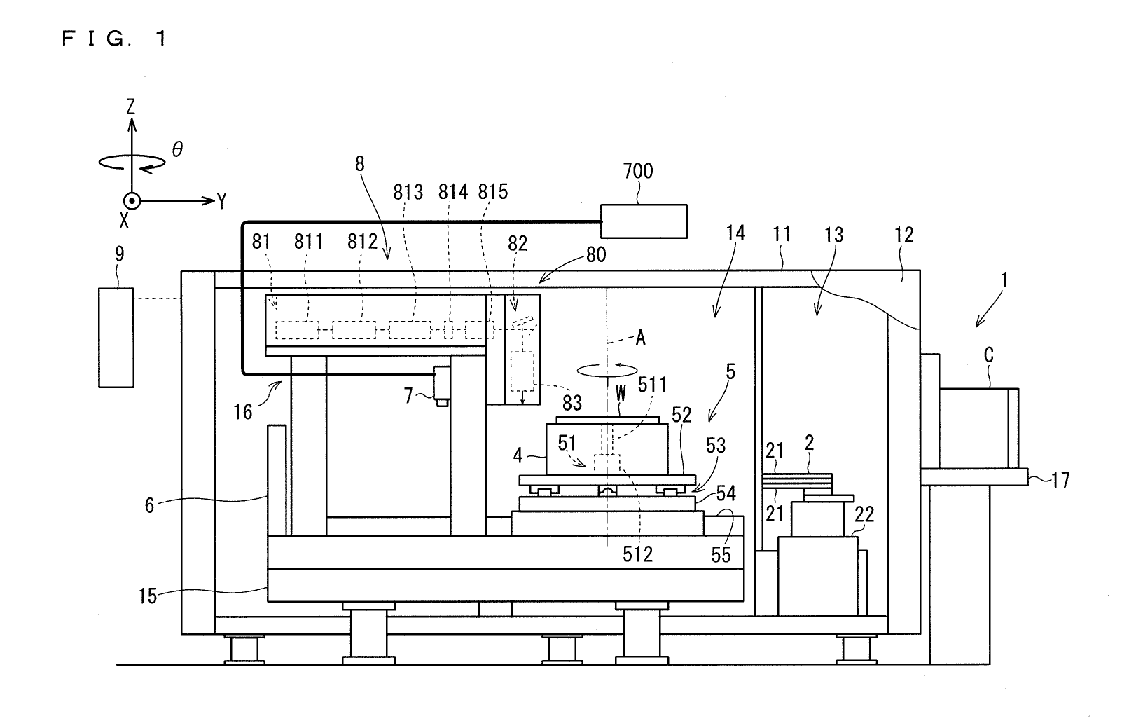

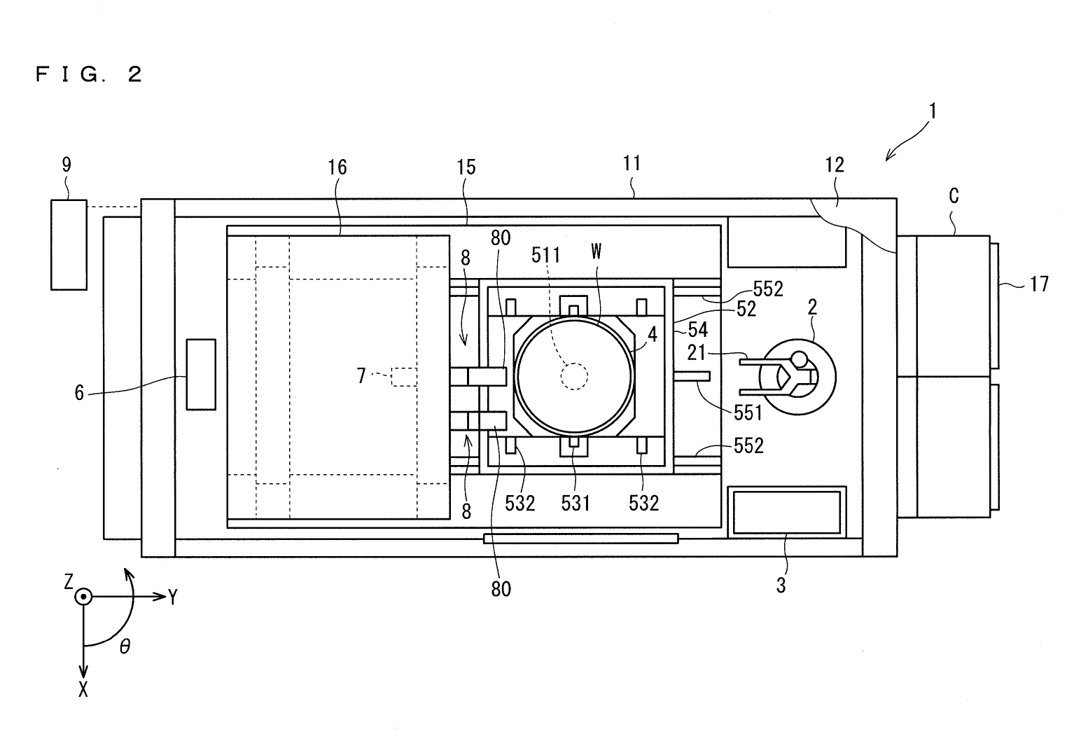

FIG. 1 is a side view schematically showing the structure of an exposure apparatus 1 of a preferred embodiment. FIG. 2 is a plan view schematically showing the structure of the exposure apparatus 1 of the preferred embodiment. For the convenience of illustration, a part of a cover panel 12 is omitted from FIGS. 1 and 2.

The exposure apparatus 1 is what is called a drawing apparatus that exposures (draw) a pattern (a circuit pattern, for example) on the upper surface of a substrate W provided with a layer of a photosensitive material such as a resist by irradiating the upper surface with light (drawing light) spatially modulated according to CAD data, for example. Examples of the substrate W to be processed by the exposure apparatus 1 include a semiconductor substrate, a print substrate, a substrate for a color filter for example provided in a liquid crystal display device, a glass substrate for a flat panel display for example provided in a liquid crystal display device or a plasma display device, a substrate for a magnetic disk, a substrate for an optical disk, and a panel for a solar cell. The following description proceeds based on the assumption that the substrate W is a circular semiconductor substrate.

The exposure apparatus 1 has a structure where a cover panel 12 is attached to the ceiling surface, the floor surface, and the surrounding surface of a framework formed of a body frame 11. The body frame 11 and the cover panel 12 form a case of the exposure apparatus 1. Space inside the case of the exposure apparatus 1 (specifically, space surrounded by the cover panel 12) is partitioned into a transferring region 13 and a processing region 14. A base 15 is arranged in the processing region 14. A portal support frame 16 is provided on the base 15.

The exposure apparatus 1 includes a transporting device 2, a pre-alignment part 3, a stage 4, a stage driving mechanism 5, a stage position measuring part 6, a mark imaging unit 7, an exposure unit 8, and a controller 9. These components are arranged inside the case of the exposure apparatus 1 (specifically, in the transferring region 13 and the processing region 14) or outside the case (specifically, in space outside the body frame 11).

<Transporting Device 2>

The transporting device 2 is for transport of a substrate W. The transporting device 2 is arranged in the transferring region 13 and brings the substrate W into and out of the processing region 14. More specifically, the transporting device 2 includes two hands 21 for supporting the substrate W and a hand driving mechanism 22 for moving the hands 21 (for making the hands 21 advance and retreat and moving the hands 21 up and down) independently.

A cassette placement part 17 for placement of a cassette C is arranged in a position outside the case of the exposure apparatus 1 and adjacent to the transferring region 13. The transporting device 2 takes out an unprocessed substrate W from the cassette C placed on the cassette placement part 17 and brings the unprocessed substrate W into the processing region 14. Further, the transporting device 2 takes out a processed substrate W from the processing region 14 and brings the processed substrate W into the cassette C. The cassette C is transferred to and from the cassette placement part 17 by an external transporting device (not shown in the drawings).

<Pre-Alignment Part 3>

The pre-alignment part 3 performs a process of correcting a rotational position of a substrate W roughly (pre-alignment process) before this substrate W is placed on the stage 4 described later. For example, the pre-alignment part 3 may include a rotatable placement table, a sensor that detects the position of a cutout (a notch or an orientation flat, for example) formed in a part of an outer periphery of a substrate W placed on the placement table, and a rotating mechanism that rotates the placement table. In this case, the pre-alignment part 3 performs the pre-alignment process by first detecting the position of a cutout in a substrate W placed on the placement table with the sensor and then rotating the placement table with the rotating mechanism so as to place the cutout at a predetermined position.

<Stage 4>

The stage 4 is a holder that holds a substrate W inside the case. The stage 4 is arranged on the base 15 placed in the processing region 14. More specifically, the stage 4 has an outer shape like a flat plate, for example, and holds a substrate W placed in a horizontal posture on the upper surface of the stage 4. The upper surface of the stage 4 is given multiple suction holes (not shown in the drawings). Negative pressure (suction pressure) acting on these suction holes is produced to allow the substrate W placed on the stage 4 to be held fixedly on the upper surface of the stage 4.

<Stage Driving Mechanism 5>

The stage driving mechanism 5 moves the stage 4 relative to the base 15. The stage driving mechanism 5 is arranged on the base 15 placed in the processing region 14.

More specifically, the stage driving mechanism 5 includes a rotating mechanism 51 that rotates the stage 4 in a rotational direction (rotational direction about the Z-axis (θ-axis direction)), a support plate 52 that supports the stage 4 through the intervention of the rotating mechanism 51, and a sub-scanning mechanism 53 that moves the support plate 52 in a sub-scanning direction (X-axis direction). The stage driving mechanism 5 further includes a base plate 54 that supports the support plate 52 through the intervention of the sub-scanning mechanism 53 and a main-scanning mechanism 55 that moves the base plate 54 in a main-scanning direction (Y-axis direction).

The rotating mechanism 51 rotates the stage 4 about a rotational axis A passing through the center of the upper surface of the stage 4 (placement surface for a substrate W) and perpendicular to the placement surface. For example, the rotating mechanism 51 may include a rotational axial part 511 extending along a vertical axis and having an upper end fixedly attached to the back side of the placement surface and a rotational driving part (a rotary motor, for example) 512 provided to the lower end of the rotational axial part 511 and used to rotate the rotational axial part 511. In this structure, rotating the rotational axial part 511 with the rotational driving part 512 causes the stage 4 to rotate in a horizontal plane about the rotational axis A.

The sub-scanning mechanism 53 has a linear motor 531 formed of a mover attached to the lower surface of the support plate 52 and a stator placed on the upper surface of the base plate 54. Guide members 532 in a pair extending in the sub-scanning direction are placed on the base plate 54. A ball bearing is placed between each of the guide members 532 and the support plate 52. The ball bearing can move along each of the guide members 532 while making sliding motion relative to this guide member 532. Specifically, the support plate 52 is supported over the guide members 532 in a pair through the intervention of the ball bearings. In this structure, operating the linear motor 531 causes the support plate 52 to move smoothly in the sub-scanning direction while the support plate 52 is guided along the guide members 532.

The main-scanning mechanism 55 has a linear motor 551 formed of a mover attached to the lower surface of the base plate 54 and a stator placed on the base 15. Guide members 552 in a pair extending in the main-scanning direction are placed on the base 15. An air bearing is placed between each of the guide members 552 and the base plate 54, for example. The air bearings receive air always supplied from a utility facility. The base plate 54 is supported over the guide members 552 in a non-contact and suspended manner with the air bearings. In this structure, operating the linear motor 551 causes the base plate 54 to move in the main-scanning direction without friction while the base plate 54 is guided along the guide members 552.

<Stage Position Measuring Part 6>

The stage position measuring part 6 measures the position of the stage 4. More specifically, the stage position measuring part 6 is, for example, formed of a laser interferometric length measuring machine that emits laser light from outside the stage 4 toward the stage 4, receives the resulting reflected light, and measures the position of the stage 4 (more specifically, a Y position in the main-scanning direction and a 0 position in the rotational direction) based on interference between the reflected light and the emitted light.

<Mark Imaging Unit 7>

The mark imaging unit 7 is an optical instrument that captures an image of the upper surface of a substrate W held on the stage 4. The mark imaging unit 7 is supported by the support frame 16. More specifically, the mark imaging unit 7 for example includes a lens barrel, a focusing lens, a CCD image sensor, and a driving part. The lens barrel is connected for example through a fiber cable to an illumination unit (illumination unit that supplies illumination light for imaging (illumination light to be selected has a wavelength that does not make a resist on a substrate W, etc., become sensitive to light)) 700 arranged outside the case of the exposure apparatus 1. The CCD image sensor is, for example, formed of an area image sensor (two-dimensional image sensor). The driving part is, for example, formed of a motor. The driving part drives the focusing lens to change the height of the focusing lens. The driving part adjusts the position of the focusing lens, thereby setting a focal point automatically.

In the mark imaging unit 7 of this structure, light emitted from the illumination unit 700 is introduced into the lens barrel. Then, the light is guided onto the upper surface of a substrate W on the stage 4 through the intervention of the focusing lens. The resulting reflected light is received by the CCD image sensor. In this way, captured image data about the upper surface of the substrate W is obtained. This captured image data is sent to the controller 9 and used for alignment (position adjustment) of the substrate W.

<Exposure Unit 8>

The exposure unit 8 is an optical device that forms drawing light. The exposure apparatus 1 includes two exposure units 8. However, two exposure units 8 are not always required. One exposure unit 8 or three or more exposure units 8 may be provided.

The exposure unit 8 includes an exposure head 80 and a light source part 81. The exposure head 80 includes a modulating unit 82 and a projection optical system 83. The light source part 81, the modulating unit 82, and the projection optical system 83 are supported by the support frame 16. More specifically, the light source part 81 is accommodated in a housing box placed on a top plate of the support frame 16. The modulating unit 82 and the projection optical system 83 are accommodated in a housing box fixed to the support frame 16 on the +Y side.

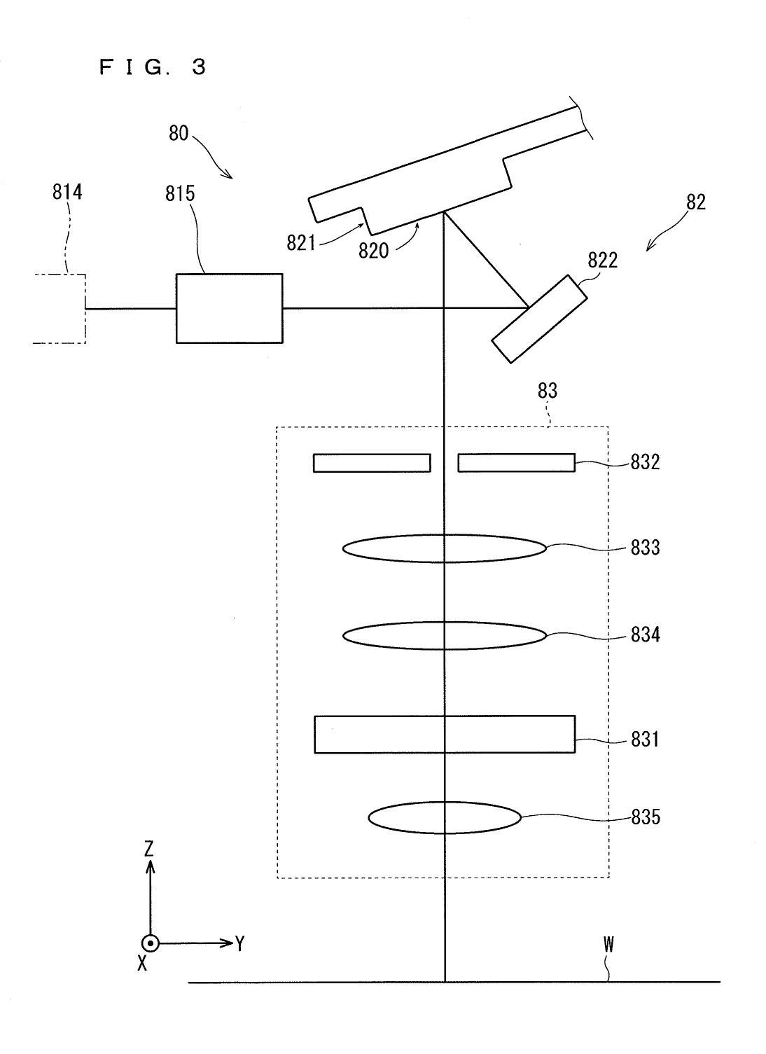

The light source part 81, the modulating unit 82, and the projection optical system 83 of the exposure unit 8 are described next by referring to FIG. 3 in addition to FIGS. 1 and 2. FIG. 3 schematically shows the exposure head 80 of the preferred embodiment.

a. Light Source Part 81

The light source part 81 emits light toward the exposure head 80. More specifically, the light source part 81 for example includes a laser driving part 811 and a laser oscillator 812 driven by the laser driving part 811 to emit laser light through an output mirror (not shown in the drawings). The light source part 81 further includes an illumination optical system 813 that converts light (spot beam) emitted from the laser oscillator 812 to linear light of a uniform intensity distribution (line beam as light having a strip-shaped beam cross section).

The light source part 81 further includes a drawing focusing lens 814 (first lens) that focuses the line beam emitted from the illumination optical system 813 on a modulation surface 820 of a spatial light modulator 821. The drawing focusing lens 814 is, for example, formed of a cylindrical lens arranged in a manner such that a cylindrical surface thereof is pointed toward an upstream side of incident light. The drawing focusing lens 814 is arranged at such a height that the line beam emitted from the illumination optical system 813 is incident on the center line of the drawing focusing lens 814 (in the below, such a height is also called a “reference position” of the drawing focusing lens 814). The drawing focusing lens 814 is provided with a mechanism that changes the height (position in the Z direction) of the drawing focusing lens 814 and the drawing focusing lens 814 may be arranged at a position above (or below) the reference position.

In the light source part 81 of the aforementioned structure, the laser oscillator 812 is driven by the laser driving part 811 to emit laser light. This laser light is converted to a line beam by the illumination optical system 813. The line beam emitted from the illumination optical system 813 enters the drawing focusing lens 814 and then exists through the cylindrical surface of the drawing focusing lens 814. Then, the line beam is focused on the modulation surface 820 of the modulating unit 82. Specifically, the modulation surface 820 functions as a light collecting surface for the line beam.

The light source part 81 includes an attenuator 815. The attenuator 815 is located on an optical path from the drawing focusing lens 814 to the modulating unit 82 (see FIGS. 1 and 3). However, this it not the only position of the attenuator 815 but the attenuator 815 can be located at any position on an optical path from the laser oscillator 812 to a substrate W. The attenuator 815 reduces light emitted from the light source part 81 based on a control signal transmitted from the controller 9. In this way, the attenuator 815 changes a light amount at multiple steps to be emitted from the light source part 81 toward the modulating unit 82.

b. Modulating Unit 82

The modulating unit 82 spatially modulates light having entered the modulating unit 82 according to pattern data. “Spatially modulating light” mentioned herein means changing a space distribution (in terms of amplitude, phase, and polarization, for example) of light. The “pattern data” mentioned herein is data containing information about a position on a substrate W stored in units of pixels. The pattern data is obtained by being received from an external terminal device connected through a network etc. or by being read from a recording medium, for example. Then, the pattern data is stored into a storage 94 of the controller 9 described later.

The modulating unit 82 includes the spatial light modulator 821. As an example, the spatial light modulator 821 is a device that spatially modulates light through electric control and reflects necessary light to contribute to pattern drawing and unnecessary light not to contribute to the pattern drawing in different directions.

As an example, the spatial light modulator 821 is formed of a diffraction grating spatial light modulator (such as a GVL) where fixed ribbons and movable ribbons as modulating elements are arranged one-dimensionally in a manner such that the upper surfaces of the fixed ribbons and those of the movable ribbons are placed along the same surface (hereinafter also called a “modulation surface”) 820. In the diffraction grating spatial light modulator 821, fixed ribbons of a given number and movable ribbons of a given number form one modulation unit. This modulation unit includes multiple modulation units arranged one-dimensionally in the X-axis direction. The spatial light modulator 821 is formed of a driver circuit unit that can apply a voltage independently to each of these modulation units. The voltage to be applied to each modulation unit can be changed independently. The level of the voltage to be applied to each modulation unit controls the operation of this modulation unit. Specifically, by controlling the voltage level, a difference in height between a reflection surface of the movable ribbon and a fixed reflection surface of the fixed ribbon can be adjusted at multiple stages. This switches light having entered each modulation unit between zero-order diffracted light and diffracted light of an order other than the zero-order, allowing change of a light amount at multiple levels (six levels, for example).

In the modulating unit 82, while the state of each modulation unit of the spatial light modulator 821 is changed according to pattern data under control of the controller 9, light (line beam) emitted from the illumination optical system 813 enters the modulation surface 820 of the spatial light modulator 821 at a given angle through the intervention of a mirror 822. The line beam enters the multiple modulation units arranged in a line in a manner such that the longitudinal direction of the linear cross section of the line beam agrees with a direction (X-axis direction) where the multiple modulation units of the spatial light modulator 821 are arranged. For this reason, light emitted from the spatial light modulator 821 becomes drawing light having a strip-shaped cross section including spatially modulated light corresponding to multiple pixels in the sub-scanning direction (light spatially modulated by one modulation unit becomes light corresponding to one pixel). In this way, the spatial light modulator 821 receives light emitted from the light source part 81 at the modulation surface 820 and spatially modulates the received light according to pattern data.

c. Projection Optical System 83

The projection optical system 83 blocks unnecessary light forming part of drawing light emitted from the spatial light modulator 821 while guiding necessary light forming part of the drawing light onto a surface of a substrate W to form an image of the necessary light on the surface of the substrate W. Specifically, the drawing light emitted from the spatial light modulator 821 includes the necessary light and the unnecessary light. The necessary light travels in the −Z direction along the Z axis. The unnecessary light travels in the −Z direction along an axis slightly tilted to the ±X direction from the Z axis. The projection optical system 83 for example includes a shielding plate 831 with a through hole formed in the center for letting only the necessary light pass through. The projection optical system 83 blocks the unnecessary light with the shielding plate 831. In addition to the shielding plate 831, the projection optical system 83 includes a shielding plate 832 with which ghost light is blocked, multiple lenses including a lens 833 and a lens 834 forming a zoom part that increases (or reduces) the width of the necessary light, a focusing lens 835 that forms an image of the necessary light on a substrate W under predetermined magnification, a driving part (such as a motor) (not shown in the drawings) that sets a focal point automatically by driving the focusing lens 835 and changing the height of the focusing lens 835, etc.

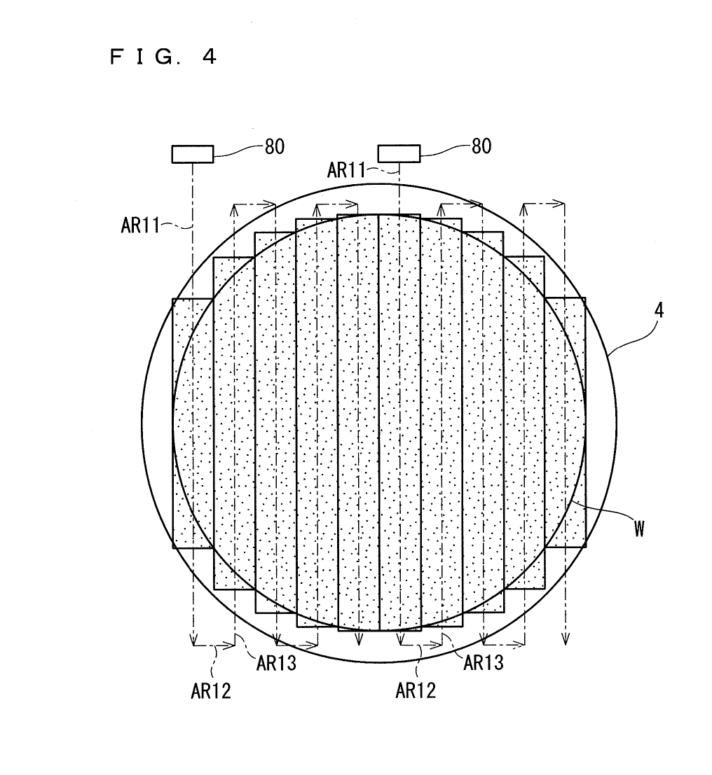

FIG. 4 is a diagrammatic plan view for explaining exposure scanning of the preferred embodiment. For the exposure scanning, the stage driving mechanism 5 moves the stage 4 in an outward direction (here, +Y direction, for example) along a main-scanning axis (Y axis), thereby moving a substrate W along the main-scanning axis relative to each exposure head 80 (outward main-scanning). The outward main-scanning from a viewpoint of the substrate W is such that each exposure head 80 traverses the substrate W in the −Y direction along the main-scanning axis, as shown by an arrow AR11. Together with start of the outward main-scanning, drawing light is applied from each exposure head 80. Specifically, pattern data (in particular, part of the pattern data describing data to be drawn in a stripe region targeted for drawing in this outward main-scanning) is read and the modulating unit 82 is controlled according to the read pattern data. Then, drawing light spatially modulated according to this pattern data is applied from each exposure head 80 toward the substrate W.

After each exposure head 80 traverses the substrate W once along the main-scanning axis while emitting the drawing light intermittently toward the substrate W, a pattern group is drawn in one stripe region (region extending along the main-scanning axis and having a width along a sub-scanning axis corresponding to the width of the drawing light). Here, the two exposure heads 80 traverse the substrate W simultaneously. Thus, a pattern group is drawn in each of two stripe regions in one outward main-scanning.

When the outward main-scanning accompanied by irradiation with the drawing light is finished, the stage driving mechanism 5 moves the stage 4 by a distance corresponding to the width of the drawing light in a given direction (−X direction, for example) along the sub-scanning axis (X axis). This moves the substrate W along the sub-scanning axis relative to each exposure head 80 (sub-scanning). The sub-scanning from a viewpoint of the substrate W is such that each exposure head 80 moves in the +X direction along the sub-scanning axis by a distance corresponding to the width of a stripe region, as shown by an arrow AR12.

When the sub-scanning is finished, return main-scanning accompanied by irradiation with the drawing light is performed. Specifically, the stage driving mechanism 5 moves the stage 4 in a return direction (here, −Y direction, for example) along the main-scanning axis (Y axis). This moves the substrate W along the main-scanning axis relative to each exposure head 80 (return main-scanning). The return main-scanning from a viewpoint of the substrate W is such that each exposure head 80 traverses the substrate W over the substrate W by moving in the +Y direction along the main-scanning axis, as shown by an arrow AR13. Together with start of the return main-scanning, each exposure head 80 starts to apply the drawing light. As a result of this return main-scanning, a pattern group is drawn in a stripe region next to the stripe region where the pattern group is drawn as a result of the previous outward main-scanning.

When the return main-scanning accompanied by irradiation with the drawing light is finished, the sub-scanning is performed. Then, the outward main-scanning accompanied by irradiation with the drawing light is performed again. As a result of this outward main-scanning, a pattern group is drawn in a stripe region next to the stripe region where the pattern group is drawn as a result of the previous return main-scanning. The main-scanning accompanied by irradiation with the drawing light is performed repeatedly thereafter while the sub-scanning is performed between one main-scanning and subsequent main-scanning. As a result, a pattern is drawn in an entire drawing target region. In this way, a drawing process according to one pattern data is finished.

<Controller 9>

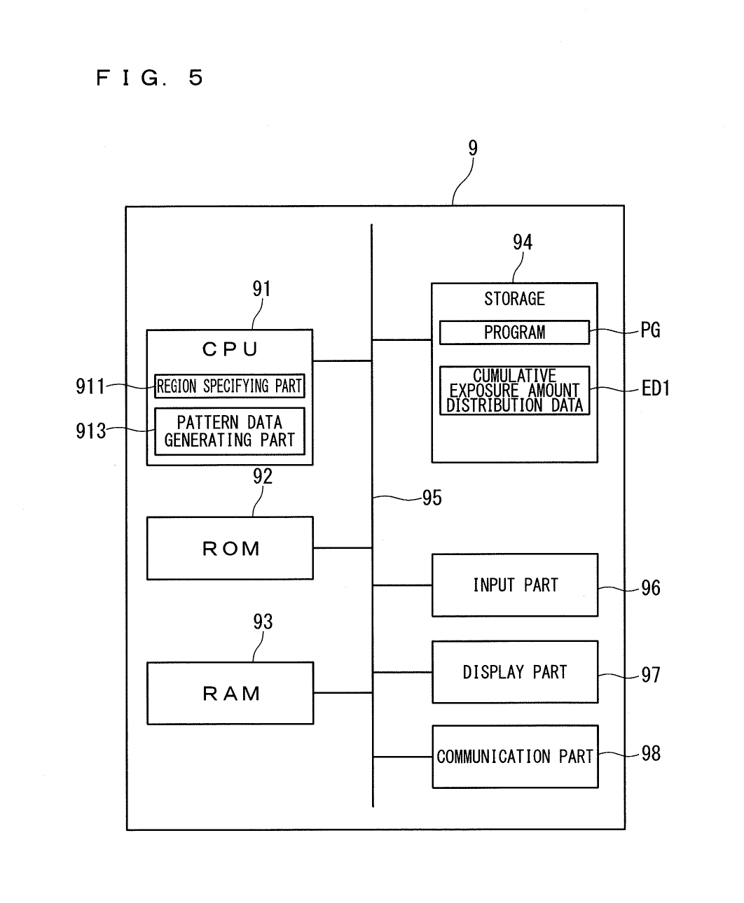

FIG. 5 is a block diagram showing the structure of the controller 9 of the preferred embodiment. The controller 9 is electrically connected to each component of the exposure apparatus 1. The controller 9 controls the operation of each component of the exposure apparatus 1 while performing various types of arithmetic processes.

As an example, the controller 9 is configured as a general-purpose computer including a CPU 91, a ROM 92, a RAM 93, the storage 94, etc. mutually connected through a bus line 95, as shown in FIG. 5. The ROM 92 stores a basic program, for example. The RAM 93 provides a working region for a given process to be performed by the CPU 91. The storage 94 is formed of a non-volatile storage such as a flash memory or a hard disk drive. A program PG is installed on the storage 94. The CPU 91 functioning as a main controller performs an arithmetic process according to a procedure described in the program PG, thereby realizing various functions (including a region specifying part 911 and a pattern data generating part 913, for example).

The program PG is generally stored in a memory such as the storage 94 when it is used. Alternatively, the program PG may be provided as a product program stored in a recording medium such as a CD-ROM, a DVD-ROM, or an external flash memory (or may be provided through download from an external server through a network, for example). In this case, the program PG may be stored as an additional or substitute program into a memory such as the storage 94. As an example, a dedicated logic circuit may be used to realize some or all of the functions in the controller 9 in terms of hardware.

The controller 9 further includes an input part 96, a display part 97, and a communication part 98 connected on the bus line 95. The input part 96 is an input device formed of a keyboard and a mouse, for example. The input part 96 accepts various operations (including entry of a command or various types of data) by an operator. Alternatively, the input part 96 may be formed of various switches or a touch panel, for example. The display part 97 is a display device formed of a liquid crystal display device or a lamp, for example. The display part 97 presents various types of information under control of the CPU 91. The communication part 98 has a data communication function of transmitting and receiving a command or data to and from an external device through a network.

### 2. Operation of Exposure Apparatus 1

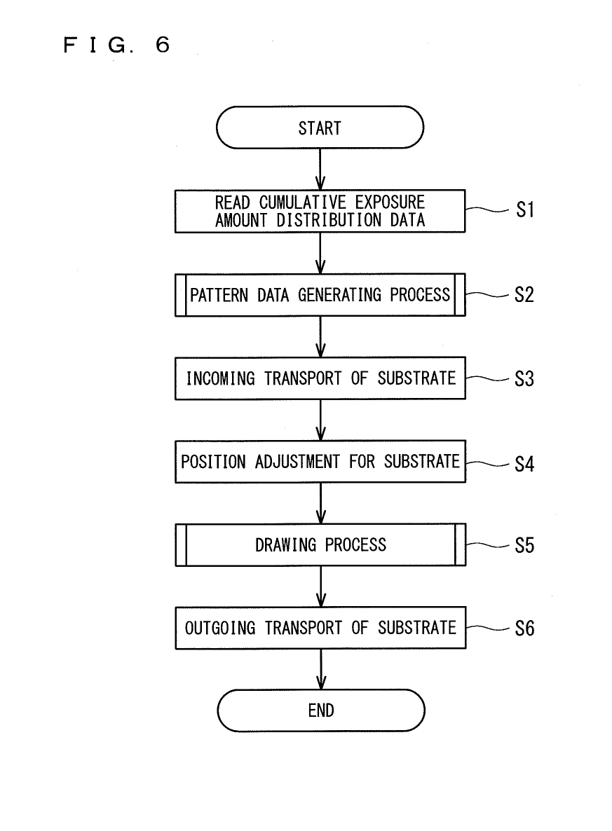

FIG. 6 shows a flow of processes performed by the exposure apparatus 1 of the preferred embodiment. A serious of operations described below are performed under control of the controller 9.

In the exposure apparatus 1, cumulative exposure amount distribution data ED1 is read first (step S1). As shown in FIG. 5, the cumulative exposure amount distribution data ED1 is stored in the storage 94. The cumulative exposure amount distribution data ED1 contains information about a position on a substrate W and information about a total amount of light to be applied to each position on the substrate W (cumulative exposure amount). The cumulative exposure amount distribution data ED1 is generated by rasterizing design data about a pattern generated by using a computer aide design (CAD). When reading of the cumulative exposure amount distribution data ED1 is finished, pattern data is generated (step S2).

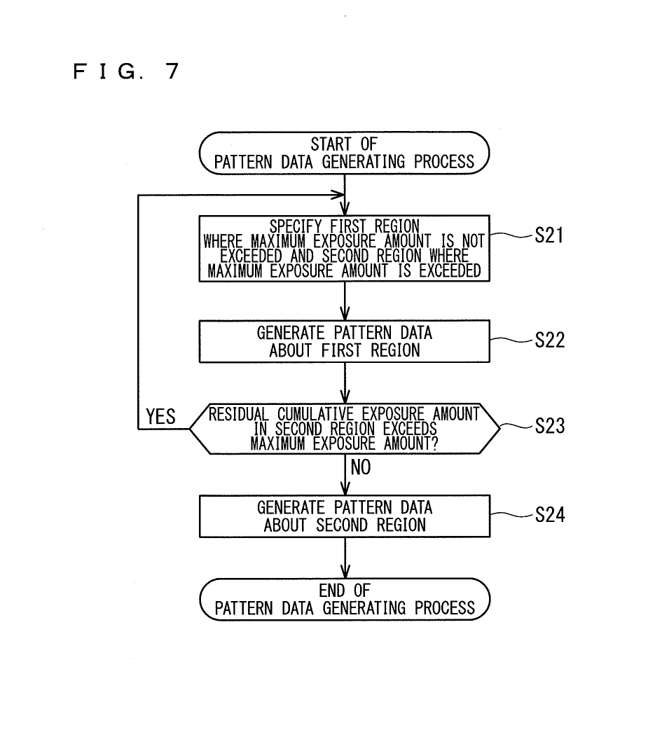

FIG. 7 shows a flow of a pattern data generating process of the preferred embodiment in detail. When the pattern data generating process is started, the region specifying part 911 first specifies a region where a cumulative exposure amount does not exceed a maximum exposure amount (first region) and a region where the cumulative exposure amount exceeds the maximum exposure amount (second region) (step S21) based on the cumulative exposure amount distribution data ED1. The “maximum exposure amount” mentioned herein means a maximum of the amount of light capable of being applied to a substrate W in one exposure scanning. “One exposure scanning” mentioned herein means moving each exposure head 80 once over a particular stripe region of the substrate W along the main-scanning axis while making this exposure head 80 emit drawing light toward the substrate W.

After the first and second regions are specified, pattern data about the first region specified in step S21 (first pattern data) is generated (step S22). This pattern data contains information about an exposure amount for each position in the first region specified in step S21 based on the cumulative exposure amount distribution data ED1.

When generation of the pattern data about the first region is finished, it is determined whether the second region includes an area where a residual cumulative exposure amount exceeds the maximum exposure amount (step S23). The residual cumulative exposure amount mentioned herein is an exposure amount determined by subtracting the exposure amount defined in the pattern data generated previously in step S22 from the cumulative exposure amount. If the second region does not include an area where the residual cumulative exposure amount exceeds the maximum exposure amount (NO of step S23), pattern data about the second region is generated (step S24). This pattern data contains information about an exposure amount for each position in a region including the second region specified in step S21 based on the cumulative exposure amount distribution data ED1.

If the second region includes an area where the residual cumulative exposure amount exceeds the maximum exposure amount (YES of step S23), the flow returns to step S21 to specify a region where the residual cumulative exposure amount does not exceed the maximum exposure amount (first region) and a region where the residual cumulative exposure amount exceeds the maximum exposure amount (second region) again within the aforementioned second region. Then, pattern data about each region is generated. In this way, a region is specified and pattern data is generated repeatedly until there is no region where the residual cumulative exposure amount exceeds the maximum exposure amount.

The flow of generating pattern data shown in FIG. 7 is described below by referring to a specific example.

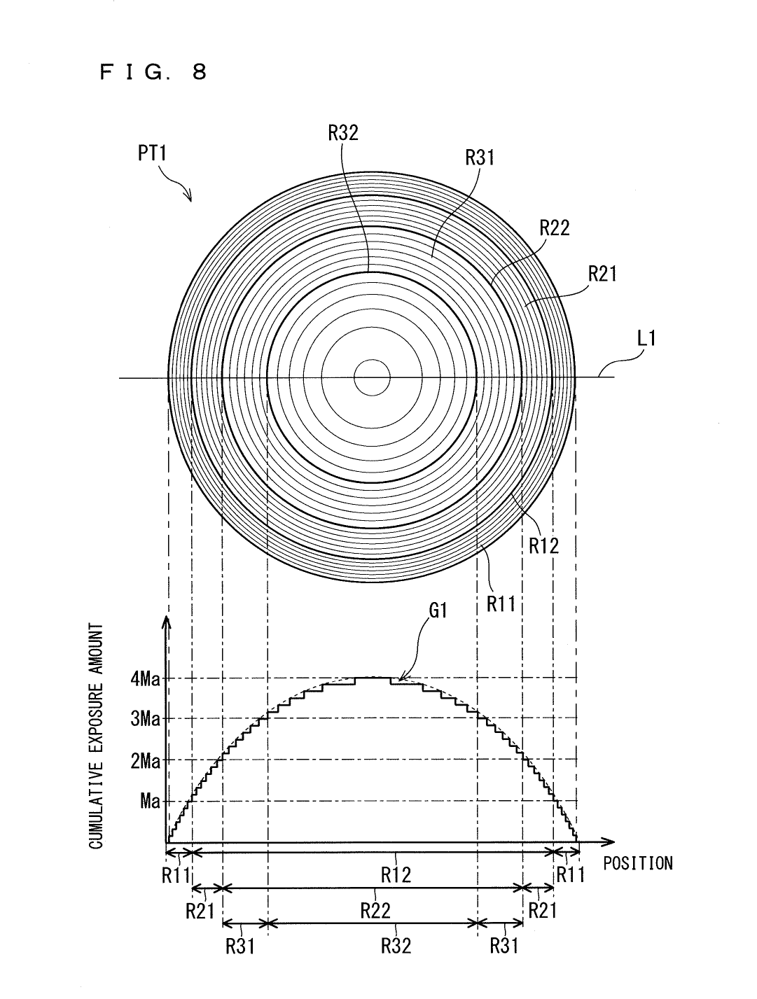

FIG. 8 shows an example of an exposure pattern together with a cumulative exposure amount distribution. FIG. 8 diagrammatically shows an exposure pattern PT1 of a microlens shape in a plan view. FIG. 8 further shows the cumulative exposure amount distribution data ED1 in a graph G1 used for generating the exposure pattern PT1. Referring to the graph G1, the horizontal axis shows a position on a substrate W (in particular, a position on a center line L1 of the exposure pattern PT1) and the vertical axis shows a cumulative exposure amount. A step of obtaining the graph G1 about the cumulative exposure amount distribution corresponds to step S1 of FIG. 6. The method of drawing a pattern shown in FIG. 6 is certainly applicable to generation of a pattern of a shape except a microlens shape.

The exposure pattern PT1 is a pattern expressed at multiple levels (here, 24 levels) of an exposure amount. According to this pattern, an exposure amount is largest in the center and is reduced stepwise with a longer distance from the center toward the outside. The exposure apparatus 1 performs the exposure scanning shown in FIG. 4 a multiple number of times to generate a pattern such as the exposure pattern PT1 on a substrate W. On the basis of the graph G1 about the cumulative exposure amount distribution, the pattern data generating part 913 generates multiple pieces of pattern data to be used for exposure scanning to be performed a corresponding number of times.

The exposure apparatus 1 is capable of performing exposure scanning a multiple number of times with a fixed maximum exposure amount or with a maximum exposure amount variable for each exposure scanning. The following describes an example of generation of pattern data with a fixed maximum exposure amount and an example of generation of pattern data with a variable maximum exposure amount separately.

<If Maximum Exposure Amount is Fixed>

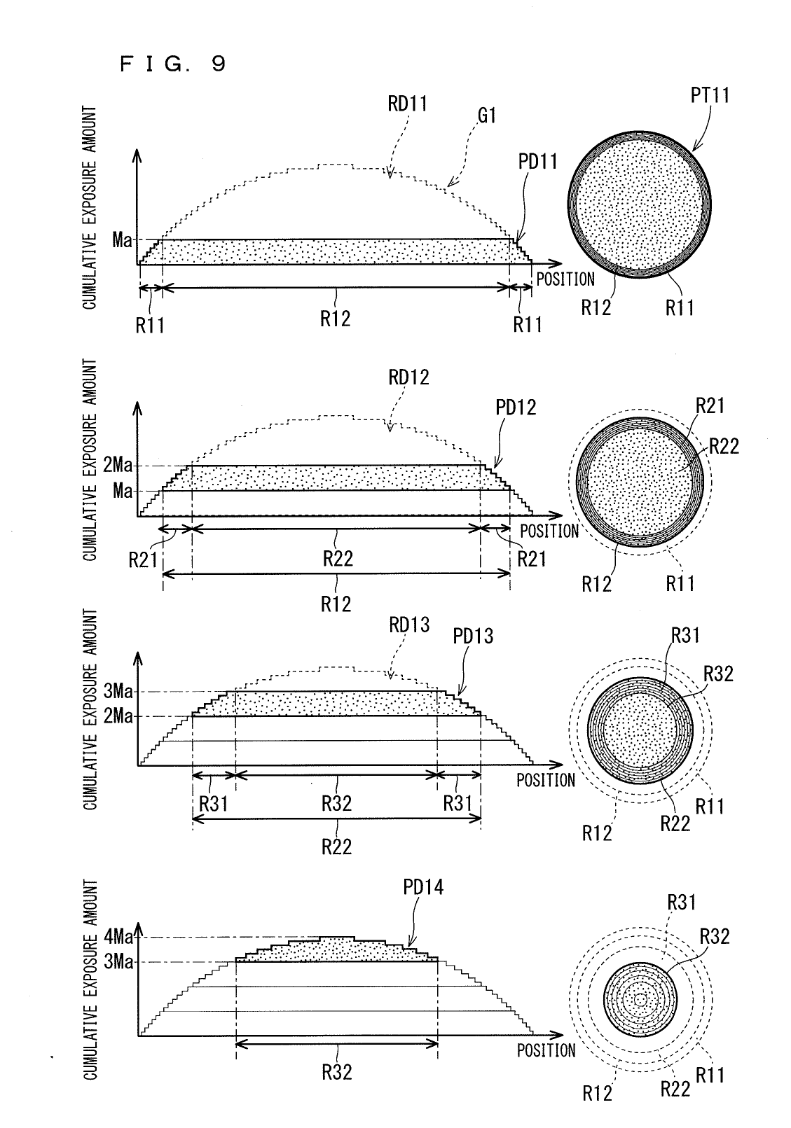

FIG. 9 conceptually shows an example of generation of pattern data with a fixed maximum exposure amount. The example of FIG. 9 shows how pattern data is generated if a maximum exposure amount for the exposure apparatus 1 is fixed at “Ma.”

First, the region specifying part 911 specifies a first region where a cumulative exposure amount does not exceed “Ma” corresponding to the maximum exposure amount for the exposure apparatus 1 and a second region where the cumulative exposure amount exceeds “Ma” based on the cumulative exposure amount distribution data ED1. In the example of the drawings, a ring-shaped region R11 in the outermost circumference of the exposure pattern PT1 is specified as the first region and a circular region R12 inside the region R11 is specified as the second region. A step of specifying the first and second regions corresponds to step S21 of FIG. 7.

After the region R11 is specified as the first region, the pattern data generating part 913 generates pattern data PD11 used for exposure of a region including the region R11. A step of generating the pattern data PD11 corresponds to step S22 of FIG. 7. As shown in FIG. 9, the pattern data PD11 contains an exposure amount for each position in the region including the region R11 (in particular, region R11 and region R12). More specifically, an exposure amount for the region R11 is an exposure amount responsive to the cumulative exposure amount distribution data ED1 and expressed at six levels from 0 to Ma. An exposure amount for the region R12 is set to Ma corresponding to the maximum exposure amount. Irradiating a substrate W with drawing light spatially modulated based on the pattern data PD11 generates a pattern PT11 where an exposure amount in the region R11 changes at six levels and the region R12 is uniformly exposed to Ma corresponding to the maximum exposure amount, as shown in FIG. 9.

Next, the pattern data generating part 913 determines whether the region R12 as the second region includes an area where a residual cumulative exposure amount RD11 exceeds “Ma” corresponding to the maximum exposure amount. This step corresponds to step S23 of FIG. 7. Specifically, the region R12 is a region where the cumulative exposure amount exceeds Ma. This cumulative exposure amount includes an amount corresponding to Ma to be applied through exposure scanning based on the previously generated pattern data PD11. Thus, the second region R12 can be considered in terms of only the residual cumulative exposure amount RD11. The region R12 includes an area where the residual cumulative exposure amount RD11 exceeds “Ma” corresponding to the maximum exposure amount. Thus, the region specifying part 911 specifies a region R21 where the residual cumulative exposure amount RD11 does not exceed Ma (first region) and a region where the residual cumulative exposure amount RD11 exceeds Ma (second region) within the second region R12 (step S21).

After the region R21 is specified as the first region, the pattern data generating part 913 generates pattern data PD12 used for exposure of a region including the region R21 (step S22). As shown in FIG. 9, the pattern data PD12 contains an exposure amount for each position in the region including the region R21 (in particular, region R21 and region R22). More specifically, an exposure amount for the region R21 is an exposure amount responsive to the residual cumulative exposure amount RD11 and expressed at six levels from 0 to Ma. An exposure amount for each position in the region R22 is determined to be Ma corresponding to the maximum exposure amount.

Next, the pattern data generating part 913 determines whether the region R22 as the second region includes an area where a residual cumulative exposure amount RD12 exceeds “Ma” corresponding to the maximum exposure amount (step S23). The region R22 is a region where the cumulative exposure amount exceeds 2Ma. This cumulative exposure amount includes an amount corresponding to 2Ma to be applied through exposure scanning based on the previously generated pattern data PD11 and pattern data PD12. Thus, the residual cumulative exposure amount RD12 in the region R22 does not include this amount corresponding to 2Ma.

The region R22 includes an area where the residual cumulative exposure amount RD12 exceeds “Ma” corresponding to the maximum exposure amount. Thus, the region specifying part 911 specifies a region R31 where the residual cumulative exposure amount RD12 does not exceed Ma (first region) and a region where the residual cumulative exposure amount RD12 exceeds Ma (second region) within the second region R22 (step S21).

After the region R31 is specified as the first region, the pattern data generating part 913 generates pattern data PD13 used for exposure of a region including the region R31 (step S22). As shown in FIG. 9, the pattern data PD13 contains an exposure amount for each position in the region including the region R31 (in particular, region R31 and region R32). More specifically, an exposure amount for the region R31 is an exposure amount responsive to the residual cumulative exposure amount RD12 and expressed at six levels from 0 to Ma. An exposure amount for each position in the region R32 is determined to be Ma corresponding to the maximum exposure amount.

Next, the pattern data generating part 913 determines whether the region R32 as the second region includes an area where a residual cumulative exposure amount RD13 exceeds “Ma” corresponding to the maximum exposure amount (step S23). The region R32 is a region where the cumulative exposure amount exceeds 3Ma. This cumulative exposure amount includes an amount corresponding to 3Ma to be applied through exposure scanning based on the previously generated pattern data PD11, pattern data PD12, and pattern data PD13. Thus, the residual cumulative exposure amount RD13 in the region R32 does not include this amount corresponding to 3Ma.

The region R32 is formed of only a region where the residual cumulative exposure amount does not exceed the maximum exposure amount Ma. Thus, the pattern data generating part 913 generates pattern data PD14 used for exposure of the region R32. This step corresponds to the step of generating pattern data about the second region (step S24 of FIG. 7). According to the pattern data PD14, an exposure amount for the region R32 is responsive to the residual cumulative exposure amount RD13 and expressed at six levels from 0 to Ma (see FIG. 9).

As described above, in this example of generation of pattern data, a region is specified and pattern data is generated repeatedly until there is no region where the residual cumulative exposure amount exceeds the maximum exposure amount Ma. If appropriate, the generated pattern data PD11, pattern data PD12, pattern data PD13, and pattern data PD14 are stored in the RAM 93 or the storage 94.

The exposure method described by referring to FIG. 9 is to generate the exposure pattern PT1 by exposing one region (such as the region R12, R22, or R32, for example) a multiple number of times. Thus, the exposure system shown in FIG. 9 is hereinafter called a stacked exposure system.

<If Maximum Exposure Amount is Changed>

The following describes an example of generation of pattern data with a maximum exposure amount changed at multiple steps. The maximum exposure amount for the exposure apparatus 1 can be changed by controlling the attenuator 815, for example.

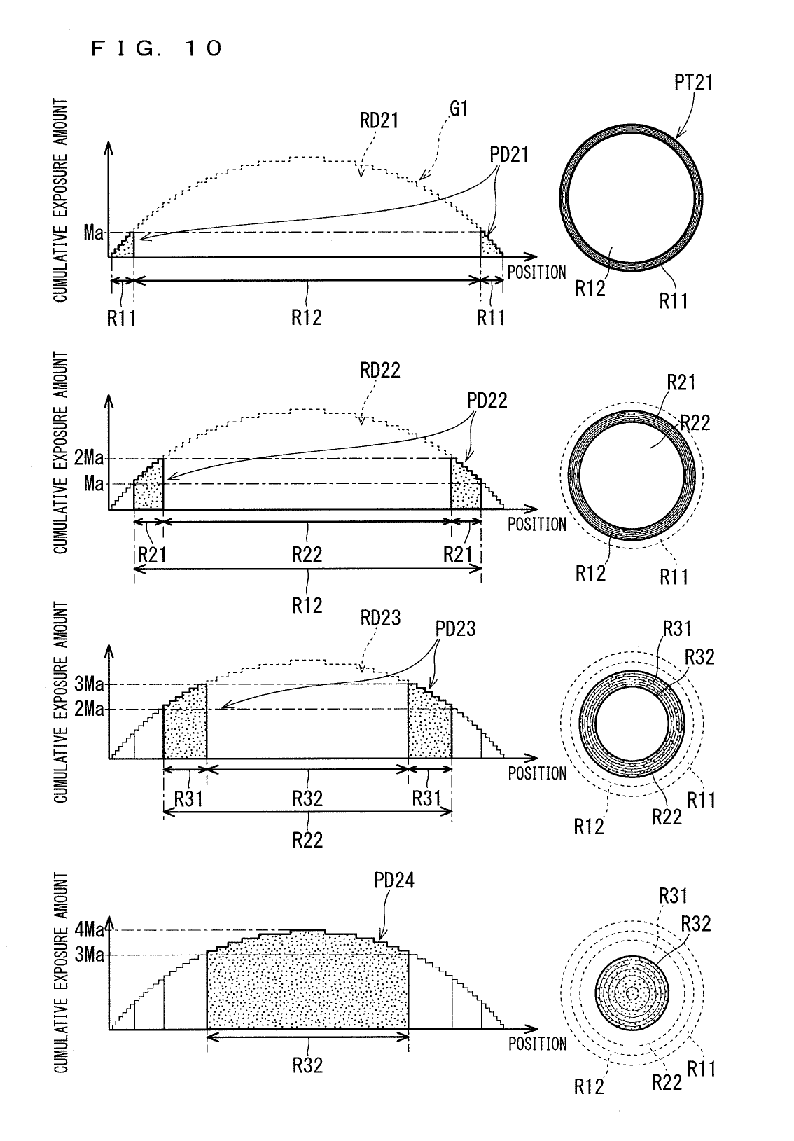

FIG. 10 conceptually shows an example of generation of pattern data with a variable maximum exposure amount. In this example, the maximum exposure amount for the exposure apparatus 1 can be changed at four steps, “Ma,” “2Ma,” “3Ma,” and “4Ma.”

In this example, the region specifying part 911 first determines a maximum exposure amount for the exposure apparatus 1 to be “Ma” corresponding to a first maximum exposure amount “Ma.” Then, the region specifying part 911 specifies a region where a cumulative exposure amount does not exceed Ma (first region) and a region where the cumulative exposure amount exceeds Ma (second region) (step S21). In this example, the region R11 is specified as the first region and the region R12 is specified as the second region.

Next, the pattern data generating part 913 generates pattern data PD21 about the region R11 as the first region (step S22). As shown in FIG. 10, according to the pattern data PD21, an exposure amount for each position in the region R11 is responsive to the cumulative exposure amount distribution data ED1, in particular, this exposure amount has six levels from 0 to Ma. In this way, the pattern data PD21 indicates information about an exposure amount for each position in the region R11. Irradiating a substrate W with light spatially modulated based on the pattern data PD21 generates a pattern PT21 where an exposure amount in the ring-shaped region R11 changes at multiple levels (six levels), as shown in FIG. 10.

Next, the pattern data generating part 913 determines whether the region R12 as the second region includes an area where a residual cumulative exposure amount RD21 exceeds “2Ma” corresponding to a second maximum exposure amount for the exposure apparatus 1 (step S23). In this example, the region R12 includes an area where the residual cumulative exposure amount RD21 exceeds “2Ma.” Thus, the region specifying part 911 specifies the region R21 where the residual cumulative exposure amount RD21 does not exceed 2Ma (first region) and the region R22 where the residual cumulative exposure amount RD21 exceeds 2Ma (second region) (step S21). Then, the pattern data generating part 913 generates pattern data PD22 about the region R21 as the first region (step S22).

As shown in FIG. 10, according to the pattern data PD22, an exposure amount for each position in the region R21 is responsive to the cumulative exposure amount distribution data ED 1 and expressed at six levels from Ma to 2Ma.

Next, the pattern data generating part 913 determines whether the region R22 as the second region includes an area where a residual cumulative exposure amount RD22 exceeds “3Ma” corresponding to a third maximum exposure amount (step S23). In this example, the region R22 includes an area where the residual cumulative exposure amount RD22 exceeds “3Ma.” Thus, the region specifying part 911 specifies the region R31 where the residual cumulative exposure amount RD22 does not exceed 3Ma (first region) and the region R32 where the residual cumulative exposure amount RD22 exceeds 3Ma (second region) (step S21). Then, the pattern data generating part 913 generates pattern data PD23 about the region R31 as the first region (step S22).

As shown in FIG. 10, according to the pattern data PD23, an exposure amount for each position in the region R31 is responsive to the cumulative exposure amount distribution data ED1 and expressed at six levels from 2Ma to 3Ma.

Next, the pattern data generating part 913 determines whether the region R32 as the second region includes an area where a residual cumulative exposure amount RD23 exceeds “4Ma” corresponding to a fourth maximum exposure amount (step S23). In this example, the region R32 does not include an area where the residual cumulative exposure amount RD23 exceeds “4Ma.” Thus, the pattern data generating part 913 generates pattern data PD24 about the region R32. This step corresponds to the step of generating pattern data about the region R32 as the second region (step S24). According to the pattern data PD24, an exposure amount for each position in the region R32 is responsive to the cumulative exposure amount distribution data ED1 and expressed at six levels from 3Ma to 4Ma.

Following the aforementioned procedure, the pattern data PD21, the pattern data PD22, the pattern data PD23, and the pattern data PD24 each corresponding to one exposure scanning are generated. The pattern data PD21, the pattern data PD22, the pattern data PD23, and the pattern data PD24 contain pieces of information used for switching a maximum exposure amount for the exposure apparatus 1 to “Ma,” “2Ma,” “3Ma,” and “4Ma” respectively. In particular, the pattern data PD21 contains information used for switching the maximum exposure amount to “Ma” and the pattern data PD22 contains information used for switching the maximum exposure amount to “2Ma.” The pattern data PD23 contains information used for switching the maximum exposure amount to “3Ma” and the pattern data PD24 contains information used for switching the maximum exposure amount to “4Ma.”

As a result of exposure scanning based on the pattern data PD21, the pattern data PD22, the pattern data PD23, and the pattern data PD24, each of the regions R11, R21, R31, and R32 is exposed only once to generate the exposure pattern PT1. Thus, the exposure system shown in FIG. 10 may hereinafter be called a one-site one-time exposure system.

Referring back to FIG. 6, when generation of the pattern data is finished, the transporting device 2 takes out an unprocessed substrate W from the cassette C placed on the cassette placement part 17 and transfers the processed substrate W onto the stage 4 in the processing region 14 (step S3). At this time, the transporting device 2 may pass through the pre-alignment part 3 with the substrate W and then transfer the substrate W onto the stage 4, if necessary. Specifically, if necessary, the transporting device 2 may once bring the unprocessed substrate W taken out from the cassette C into the pre-alignment part 3. Then, the transporting device 2 may take out the substrate W after subjected to the pre-alignment process from the pre-alignment part 3 and transfer this substrate W onto the stage 4.

After the substrate W is placed on the stage 4 and the substrate W is held on the stage 4 under suction, the stage driving mechanism 5 moves the stage 4 to a position below the mark imaging unit 7. After the stage 4 is placed below the mark imaging unit 7, a process of precisely adjusting the position of the substrate W is performed (alignment process) to place the substrate W at a proper position on the stage 4 (step S4). When the position adjustment for the substrate W is finished, a drawing process is performed (step S5).

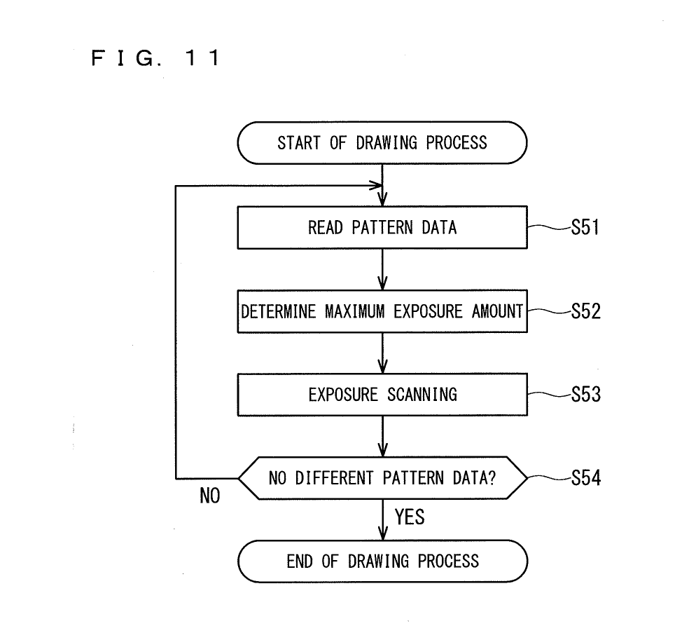

FIG. 11 shows a flow of the drawing process of FIG. 6 in detail. In response to start of the drawing process, pattern data is read (step S51). In this flow, the pattern data generated in step S2 is read. As an example, if the pattern data PD11, the pattern data PD12, the pattern data PD13, and the pattern data PD14 shown in FIG. 9 are generated, one of these pieces of the pattern data is read.

After the pattern data is read, a maximum exposure amount capable of being applied in one exposure scanning by the exposure apparatus 1 is determined based on information stored in the read pattern data (step S52). As described above, the maximum exposure amount for the exposure apparatus 1 is changed by controlling the attenuator 815. If the pattern data is generated with a fixed maximum exposure amount as in the example of generation of pattern data shown in FIG. 9, the step S52 may be omitted.

After the maximum exposure amount is determined, exposure scanning is performed (step S53). As described above by referring to FIG. 4, for the exposure scanning, while each exposure head 80 moves relative to the substrate W, each exposure head 80 applies drawing light spatially modulated according to the pattern data toward the upper surface of the substrate W. In this way, one exposure scanning on the substrate W is finished based on one pattern data.

In the example of FIG. 4, during one exposure scanning, drawing light moves once in all stripe regions on the substrate W. Alternatively, exposure scanning may be omitted regarding a stripe region on the substrate W not requiring exposure. Specifically, only a stripe region requiring exposure may be subjected to exposure scanning.

When the exposure scanning is finished, the existence of different pattern data is determined (step S54). If there is no different pattern data (YES of step S54), the drawing process is finished and the flow proceeds to step S6 of FIG. 6. If there is different pattern data (NO of step S54), the flow returns to step S51. Then, the maximum exposure amount is determined (step S52) and exposure scanning is performed (step S53) again based on this different pattern data.

Referring back to FIG. 6, when the drawing process is finished, the transporting device 2 receives the processed substrate W from the stage 4 and houses the processed substrate W in the cassette C (step S6). In this way, a series of the processes on this substrate W is finished. After housing the processed substrate W in the cassette C, the transporting device 2 takes out a new unprocessed substrate W from the cassette C. Then, the series of the aforementioned processes is started on this new substrate W.

### 3. Advantageous Effects

In the aforementioned preferred embodiment, multiple pieces of pattern data (for example, pattern data PD11, pattern data PD12, pattern data PD13, and pattern data PD14, and pattern data PD21, pattern data PD22, pattern data PD23, and pattern data PD24) based on one cumulative exposure amount distribution data ED1 and exposure scanning is performed a multiple number of times based on corresponding pattern data. Thus, in the exposure apparatus 1 where a pattern to be generated can be expressed only at six levels through one exposure scanning, employing the stacked exposure system or the one-site one-time exposure system makes it possible to produce an exposure amount larger than a maximum exposure amount. As a result, a pattern expressed at levels of an exposure amount exceeding six levels (such as the exposure pattern PT1 at 24 levels) can be generated on a substrate W.

In the aforementioned preferred embodiment, exposure scanning is performed continuously while a substrate W is not transported outward for each exposure scanning. This can suppress shift of the position of the substrate W between each exposure scanning and different exposure scanning. As a result, a position where a pattern is to be generated can be aligned precisely between each exposure scanning and different exposure scanning.

As described by referring to FIG. 9, in the case of the stacked exposure system of performing each exposure scanning with a fixed maximum exposure amount for the exposure apparatus 1, a process of calibrating a light amount can be omitted that is to be performed for each exposure scanning. As a result, a pattern can be generated promptly.

Depending on a cumulative exposure amount distribution about a pattern to be generated, the one-site one-time exposure system described by referring to FIG. 10 may bring advantage over the stacked exposure system described by referring to FIG. 9 in terms of reducing the number of times exposure scanning is performed. Specifically, the stacked exposure system uses a fixed maximum exposure amount. Thus, for an area where a cumulative exposure amount is maximum, for example, this area should be subjected to exposure scanning a number of times (N times, for example) determined by dividing this maximum of the cumulative exposure amount by the fixed maximum exposure amount. In contrast, in the case of the one-site one-time exposure system, by increasing the maximum exposure amount, only one exposure scanning (or exposure scanning to be performed a number of times smaller than the N times) becomes necessary for the area where the cumulative exposure amount is maximum.

To perform exposure a multiple number of times like in the aforementioned case in an exposure apparatus employing a conventional mask exposure system with the intention of increasing the number of levels of an exposure amount, multiple masks (reticles) should be prepared, causing a risk of cost increase. Additionally, a mask should be exchanged for each exposure. This may prolong a time of a job or cause a risk of the occurrence of contamination. Further, an exposure position should be adjusted precisely during exchange of a mask, causing a risk of complicating the job. In contrast, in the case of the exposure apparatus 1 employing the maskless exposure system of the preferred embodiment, what is required is only to prepare pattern data for each exposure scanning. This can easily achieve exposure at multiple levels without causing considerable increase in cost or workload.

<Modifications>

If a maximum exposure amount for the exposure apparatus 1 is fixed during generation of multiple pieces of pattern data to be used for exposure scanning to be performed a corresponding number of times, for example, an element for changing a light amount such as the attenuator 815 may be omitted.

In the aforementioned preferred embodiment, the attenuator 815 changes a light amount to change a maximum exposure amount for the exposure apparatus 1. Alternatively, the maximum exposure amount can be changed by changing a speed of movement of the exposure head 80 relative to a substrate W during exposure scanning. Specifically, the maximum exposure amount can be reduced by increasing the speed of movement while the maximum exposure amount can be increased by reducing the speed of movement.

In the exposure systems described by referring to FIGS. 9 and 10, each pattern data is generated with a maximum exposure amount constant throughout every exposure scanning or differing between each exposure scanning and different exposure scanning. Alternatively, each pattern data may be generated in a manner such that a pattern is generated by a combination of exposure scanning to be performed twice or more with the same maximum exposure amount and exposure scanning to be performed twice or more with respective maximum exposure amounts.

In the stacked exposure system described by referring to FIG. 9, a maximum exposure amount for each exposure scanning is fixed. Alternatively, a stacked exposure system accompanied by change in the maximum exposure amount is also applicable. Specifically, exposure scanning may be performed a multiple number of times on the same region while the maximum exposure amount is changed.

In the aforementioned preferred embodiment, a diffraction grating spatial light modulator is used as the spatial light modulator 821. However, this is not the only structure of the spatial light modulator 821. The spatial light modulator 821 may alternatively be a spatial light modulator including modulation units such as mirrors arranged one-dimensionally or two-dimensionally, for example. As an example, a digital micromirror device (DMD) is applicable.

While the invention has been described in detail, the foregoing description is in all aspects illustrative and not restrictive. It is therefore understood that numerous modifications and variations can be devised without departing from the scope of the invention.

What is claimed is:

1. A drawing method of drawing a pattern on a substrate, comprising the steps of:
(a) drawing a pattern on a substrate through irradiation of a region on said substrate including a first region with light spatially modulated based on first pattern data by an exposure apparatus, said first region being a region where a cumulative exposure amount to be applied does not exceed a first maximum exposure amount capable of being applied to said substrate in one exposure scanning by said exposure apparatus; and
(b) drawing a pattern on said substrate through irradiation of a region on said substrate including a second region with light spatially modulated based on second pattern data by said exposure apparatus, said second region being a region where said cumulative exposure amount exceeds said first maximum exposure amount, said second pattern data containing information about an exposure amount for each position.

2. The drawing method according to claim 1, further comprising the steps of:
(c) reading cumulative exposure amount distribution data containing information about a position on said substrate and said cumulative exposure amount for each position, said step (c) being performed before said step (a);
(d) specifying said first region and said second region on said substrate based on said cumulative exposure amount distribution data read in step (c); and
(e) generating said first pattern data and said second pattern data for said region including said first region specified in said step (d) and for said region including said second region specified in said step (d) respectively, said first pattern data and said second pattern data each containing an exposure amount for each position.

3. The drawing method according to claim 1, wherein said step (b) is a step of switching said maximum exposure amount for said exposure apparatus from said first maximum exposure amount to a second maximum exposure amount larger than said first maximum exposure amount and then exposing said region including said second region.

4. The drawing method according to claim 1, wherein said maximum exposure amount for said exposure apparatus is determined to be said first maximum exposure amount both in said steps (a) and (b).
